(19) United States
(12) Patent Application Publication
(10) Pub. No.: US 2008/0205170 A1
(43) Pub. Date: Aug. 28, 2008

(54) DDR-SDRAM INTERFACE CIRCUITRY, AND METHOD AND SYSTEM FOR TESTING THE INTERFACE CIRCUITRY

(75) Inventor: Shinichiro IKEDA, Kasugai-shi (JP)

Correspondence Address: ARENT FOX LLP, 1050 CONNECTICUT AVENUE, N.W., SUITE 400, WASHINGTON, DC, 20036, US

(73) Assignee: FUJITSU LIMITED

(21) Appl. No.: 12/039,316

(22) Filed: Feb. 28, 2008

(30) Foreign Application Priority Data
Feb. 28, 2007 (JP) 2007-048420

(51) Int. Cl. G11C 7/00; G11C 8/00

(52) U.S. Cl. 365/193; 365/194; 365/201; 365/233.11

(57) ABSTRACT

According to one aspect of an embodiment of the present invention, there is provided a memory interface circuit including a first data output circuit which outputs a data signal based on a data strobe signal, the memory interface circuit comprising: a first delay-locked loop circuit that adjusts a delay of the data strobe signal and outputs the data strobe signal at a first timing; and a second data output circuit that outputs the data signal at a second timing different from the first timing during a normal operation, and outputs the data signal at the first timing during a test operation.

### CROSS-REFERENCE TO RELATED APPLICATIONS

This application claims the benefit of priority from Japanese Patent Application No. 2007-048420 filed on Feb. 28, 2007, the entire contents of which are incorporated herein by reference.

### BACKGROUND OF THE INVENTION

1. Field of the Invention

This application is related to a DDR-SDRAM interface circuit.

2. Description of Related Art

DDR-SDRAM (Double Data Rate Synchronous Dynamic Random Access Memory) is capable of transferring data in synchronization with each of the rising and falling edges of a clock and is therefore capable of realizing a data throughput twice that of an SDRAM. In accordance with the DDR-SDRAM standard, timing of transmission/reception of data signals is optimized by using a bidirectional data strobe signal. In this case, the phase relationship between the data strobe signal and the data signal at the data transmission (data write) from an interface circuit to the DDR-SDRAM is different from that of the data reception (data read) at the interface circuit. The timings of the edges of the data strobe signal and the data signal differ by 90° when writing and coincide with each other when reading.

As a shipping test on a semiconductor device having a DDR-SDRAM interface circuit, an at-speed test in which a function test is performed at an actual speed is known. Japanese Laid-open Patent Publication No. 2006-85650 and Japanese Laid-open Patent Publication No. 8-62298 disclose examples of testing methods.

### SUMMARY

According to one aspect of an embodiment of the present invention, there is provided a memory interface circuit including a first data output circuit which outputs a data signal based on a data strobe signal, the memory interface circuit comprising: a first delay-locked loop circuit that adjusts a delay of the data strobe signal and outputs the data strobe signal at a first timing; and a second data output circuit that outputs the data signal at a second timing different from the first timing during a normal operation, and outputs the data signal at the first timing during a test operation.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 is a diagram showing the circuit configuration of a DDR-SDRAM interface circuit.

FIG. 2 is a timing chart of the DDR-SDRAM interface circuit.

FIG. 3 is a diagram showing the circuit configuration of a first embodiment.

FIG. 4 is a timing chart of the first embodiment;

FIG. 5 is a diagram showing the circuit configuration of a second embodiment.

FIG. 6 is a timing chart of the second embodiment.

FIG. 7 is a diagram showing the circuit configuration of a third embodiment.

FIG. 8 is a diagram showing the circuit configuration of a fourth embodiment.

FIG. 9 is a diagram showing the circuit configuration of a determination section 4a.

FIG. 10 is a diagram showing an example of changing a clock by a DLL circuit 17.

### DESCRIPTION OF THE PREFERRED EMBODIMENTS

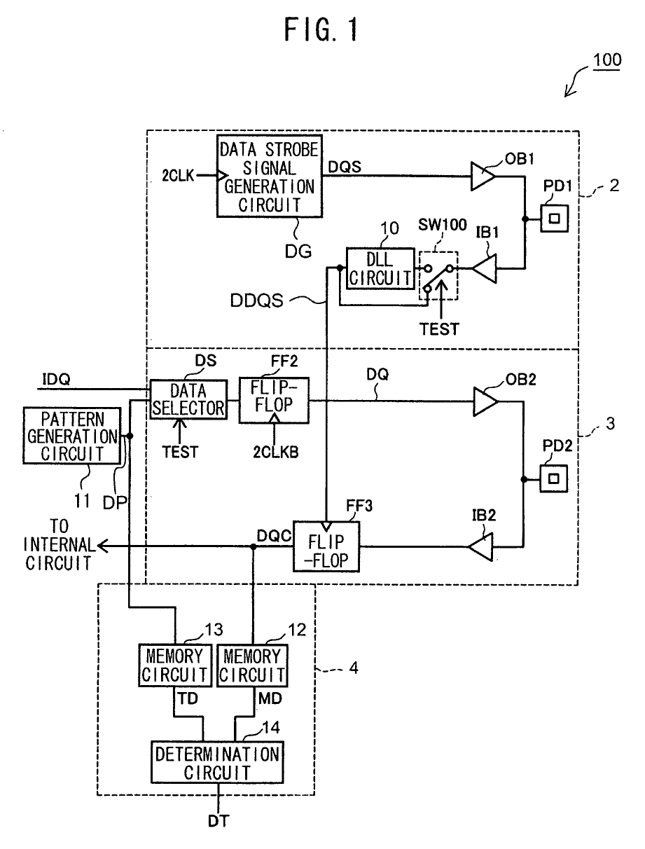

The operation for a loopback test is described with reference to a circuit diagram of a DDR-SDRAM interface circuit 100 in FIG. 1. In a loopback test mode, a data strobe signal DQS and a data signal DQ output from DDR-SDRAM interface circuit 100 for data writing are fed back to be returned to the DDR-SDRAM interface circuit 100. The signals are returned in a state of having a phase difference of 90° there between, such that the toggle edges of the data strobe signal DQS generally coincide with centers of portions of the data signal DQ. In this case, when the data strobe signal DQS is input into a DLL circuit 10, a delayed data strobe signal DDQS further phase-delayed by 90°, is output from the DLL circuit 10. The phase difference between the edges of the delayed data strobe signal DDQS and the data signal DQ is 180° and the edges of the two signals are phase aligned with each other. At this time, in a flip-flop FF3, the data signal cannot be captured by using the delayed data strobe signal DDQS and, therefore, the loopback test cannot be performed.

In the loopback test, therefore, the data strobe signal DQS is fed back and applied to the DDR-SDRAM interface circuit 100 and is directly input into the flip-flop FF3 by using a switch SW100 forming a bypass around the DLL circuit 10. In this case, the toggle edges of the data strobe signal DQS has a phase difference of 90° to set it generally in correspondence with centers of portions of the data signal DQ. As a result, the data signal DQ can be captured in the flip-flop FF3, thus enabling the loopback test.

In a normal mode, a test control signal TEST is set to a low level. The switch SW100 selects the DLL circuit 10 as a destination of connection of an output terminal of an input buffer IB1 according to the test control signal TEST at a low level. A data selector DS selects an internal data signal IDQ as data to be input into a flip-flop FF2. In the normal mode, data communication with a DDR-SDRAM (not shown) via input/output pads PD1 and PD2 is performed.

The test control signal TEST is set to high level by a control circuit (not shown) to enter the loopback test mode. In response to transition of the test control signal TEST to high level, the switch SW100 changes the destination of connection of the output terminal of the input buffer IB1 from the DLL circuit 10 to the flip-flop FF3. Therefore, the DLL circuit 10 is bypassed. The data selector DS changes data to be input into the flip-flop FF2 from the internal data signal IDQ to pattern data DP according to the test control signal TEST at high level.

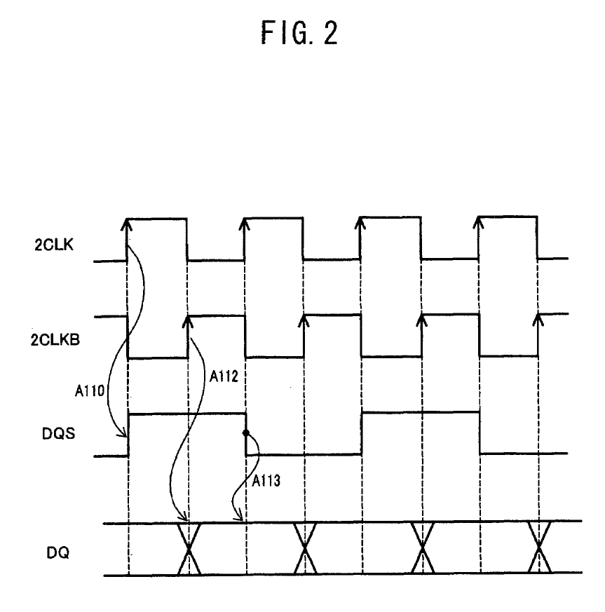

In a data strobe signal generation circuit DG, the data strobe signal DQS is generated. As shown in the timing chart of FIG. 2, the data strobe signal DQS is obtained by dividing an internal clock signal 2CLK by two in correspondence with the rising edges of the internal clock signal 2CLK (arrow A110 in FIG. 2). The data strobe signal DQS output from the data strobe signal generation circuit DG is input into the flip-flop FF3 via an output buffer OB1, the input buffer IB1 and the switch SW100. That is, the data strobe signal DQS output from the data strobe signal generation circuit DG is input into the flip-flop FF3 by bypassing the DLL circuit 10.

The flip-flop FF2 produces the data signal DQ according to an internal opposite-phase clock signal 2CLKB input thereto. As shown in FIG. 2, the data signal DQ is obtained by dividing the internal opposite-phase clock signal 2CLKB by two in correspondence with the rising edges of the internal opposite-phase clock signal 2CLKB (arrow A112 in FIG. 2). The data signal DQ output from the flip-flop FF2 is input into the flip-flop FF3 via an output buffer OB2 and an input buffer IB2. The flip-flop FF3 captures the data signal DQ in correspondence with the toggle edges of the data strobe signal DQS (arrow A113 in FIG. 2).

The data signal DQ captured by the flip-flop FF3 is successively held in a memory circuit 12. The pattern data DP output from a pattern generation circuit 11 is successively held in a memory circuit 13. Test result data MD output from the memory circuit 12 and output pattern data TD output from the memory circuit 13 are input into a determination circuit 14. In the determination circuit 14, a determination is made as to whether or not the test result data MD and the output pattern data TD coincide with each other.

If the DDR-SDRAM interface circuit 100 has setup/hold characteristics in conformity with the standard, the data signal DQ output from the pattern generation circuit 11 can be correctly captured by the flip-flop FF3 in accordance with the above-described data loopback procedure. Then the determination circuit 14 outputs a determination signal DT indicating that the output pattern data TD, which is an expected value pattern, and the test result data MD coincide with each other. If the DDR-SDRAM interface circuit 100 does not have the setup/hold characteristics in conformity with the standard, the determination circuit 14 outputs a determination signal DT indicating that the output pattern data TD and the test result data MD do not coincide with each other.

The reason that the DLL circuit 10 is bypassed during the loopback test is described. The data strobe signal DQS and the data signal having a phase difference of 90° there between such that the toggle edges of the data strobe signal DQS generally coincide with centers of portions of the data signal DQ, are returned to the DDR-SDRAM interface circuit 100. In this case, if the DLL circuit 10 is not bypassed, the phase of the data strobe signal DQS delayed by 90° from the data signal DQ is further delayed by 90° by the DLL circuit 10. The phase difference between the edges of the delayed data strobe signal DDQS output from the DLL circuit 10 and the data signal DQ is 180°. The edges of the two signals are thereby phase-aligned with each other, so that the data signal DQ cannot be captured by the flip-flop FF3, resulting in failure to perform the loopback test.

In the loopback test, therefore, the data strobe signal DQS fed back is supplied through a bypass around the DLL circuit 10. Since the data strobe signal DQS having such a phase difference has toggle edges that generally coincide with centers of portions of the data signal DQ, it is thereby input into the flip-flop FF3, and the data signal DQ can be captured according to the data strobe signal.

In the loopback test, however, various tests including an at-speed test with respect to the DLL circuit 10 cannot be performed since the DLL circuit 10 is bypassed. Moreover, a roundtrip delay in the path from the data strobe signal generation circuit DG to the flip-flop FF3 for example cannot be performed.

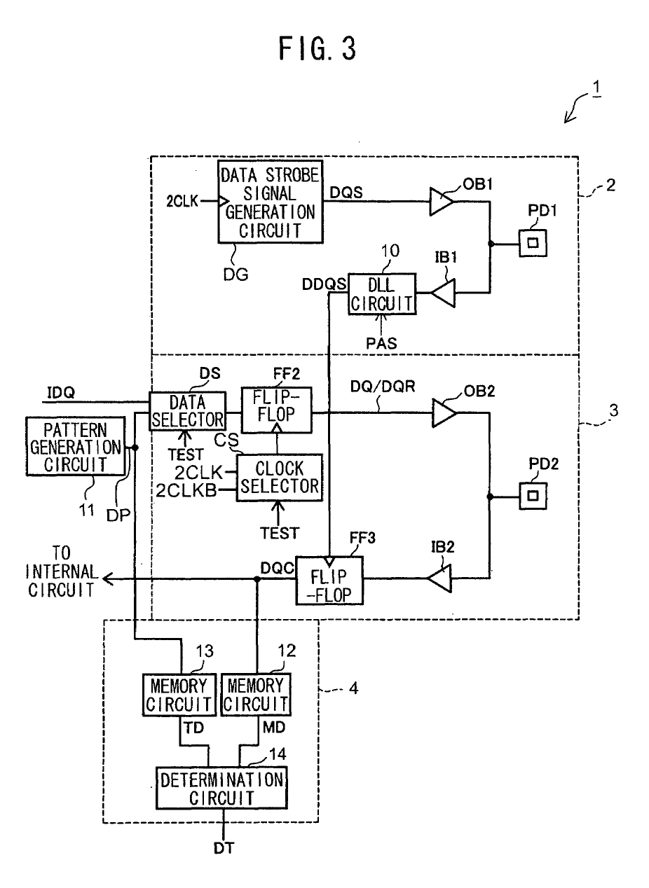

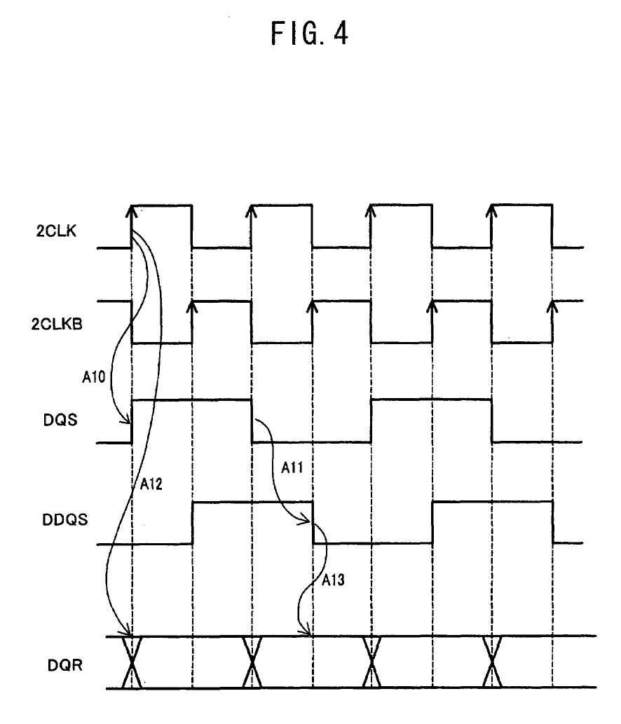

FIGS. 3 and 4 show a first embodiment. FIG. 3 is a diagram showing the circuit configuration of the first embodiment. A DDR-SDRAM interface circuit 1 includes a data strobe signal input/output section 2, a data signal input/output section 3, a determination section 4 and a pattern generation circuit 11.

The data strobe signal input/output section 2 includes a data strobe signal generation circuit DG, an output buffer OB1, an input/output pad PD1, an input buffer IB1 and a DLL circuit 10. An internal clock signal 2CLK is input into the data strobe signal generation circuit DG. A data strobe signal DQS output from the data strobe signal generation circuit DG is output to the input/output pad PD1 and to the input buffer IB1 via the output buffer OB1. The input/output pad PD1 is a pad for connection to a DDR-SDRAM (not shown). The data strobe signal DQS via the input buffer IB1 is input into the DLL circuit 10. A delayed data strobe signal DDQS is output from the DLL circuit 10. A phase adjustment signal PAS is input into the DLL circuit 10 from the control circuit (not shown).

The data signal input/output section 3 includes a data selector DS, a flip-flop FF2 for data signal output, a clock selector CS, an output buffer OB2, an input/output pad PD2, an input buffer IB2, and a flip-flop FF3 for data signal capture. An internal data signal IDQ output from an internal circuit (not shown), pattern data DP output from a pattern generation circuit 11 and a test control signal TEST are input into the data selector DS. An internal clock signal 2CLK, an internal opposite-phase clock signal 2CLKB and a test control signal TEST are input into the clock selector CS. The internal opposite-phase clock signal 2CLKB is a clock signal in phase opposition to the internal clock signal 2CLK. A data signal DQ or a delayed data signal DQR is output from the flip-flop FF2. The data signal DQ is a signal generated based on the internal opposite-phase clock signal 2CLKB, while the delayed data signal DQR is a signal generated based on the internal clock signal 2CLK. The data signal DQ or the delayed data signal DQR is output to the input/output pad PD2 and to the input buffer IB2 via the output buffer OB2. The input/output pad PD2 is a pad for connection to the DDR-SDRAM (not shown). The data signal DQ or the delayed data signal DQR output from the input buffer IB2 is input into the flip-flop FF3. An obtained data signal DQC is output from the flip-flop FF3 and is input into the determination section 4 and to the internal circuit (not shown).

The determination section 4 includes memory circuits 12 and 13 and a determination circuit 14. The obtained data signal DQC is input to the memory circuit 12, while pattern data DP is input to the memory circuit 13. Test result data MD output from the memory circuit 12 and output pattern data TD13 output from the memory circuit 13 are input into the determination circuit 14. A determination signal DT is output from the determination circuit 14.

The loopback test operation of the DDR-SDRAM interface circuit 1 is described. The DDR-SDRAM interface circuit 1 outputs the data strobe signal DQS and the data signal DQ to the DDR-SDRAM (not shown) when writing data. The DDR-SDRAM interface circuit 1 receives the data strobe signal DQS and the data signal DQ from the DDR-SDRAM when reading data. Also, the DDR-SDRAM interface circuit 1 has a normal operation mode during which communication of the data signal DQ with the DDR-SDRAM is performed, and a test mode during which the DDR-SDRAM interface circuit 1 checks its own operation. A shipping test on the DDR-SDRAM interface circuit 1 executed during the test mode includes an at-speed test in which the functions are tested at the actual speed. The data transfer rate of the DDR-SDRAM is extremely high. Therefore, a high-speed tester is required to perform the at-speed test. However, because the high-speed tester is very expensive, the loopback test is performed.

In the loopback test, the data strobe signal DQS, output through the output buffer OB1, is turned back to be input into the input buffer IB1. The data signal DQ output through the output buffer OB2, is turned back to be input, to the input buffer IB2. The turned-back data signal DQ is captured by the flip-flop FF3 in the data signal input/output section 3 using the turned-back data strobe signal DQS. Determination is made as to whether the captured data and the original data coincide with each other. In this case, a tester may only perform data coincidence determination. Thus, the at-speed test on the DDR-SDRAM interface circuit 1 can be performed by using a low-priced low-speed tester. There is no need to provide a special tester for generation and reception of a test pattern, and various tests can be performed with a simple arrangement.

The operation of the first embodiment is described. In the normal mode, the test control signal TEST is set to a low level. The clock selector CS selects the internal opposite-phase clock signal 2CLKB as a clock signal to be input into the flip-flop FF2 according to the low-level test control signal. The data selector DS selects the internal data signal IDQ as data to be input into the flip-flop FF2.

When the test control signal TEST is set to a high level by the control circuit (not shown), the interface circuit 1 enters the loopback test mode. The clock selector CS changes the clock signal to be input into the flip-flop FF2 from the internal opposite-phase clock signal 2CLKB to the internal clock signal 2CLK with the transition of the test control signal TEST to the high level. The data selector DS changes the data to be input into the flip-flop FF2 from the internal data signal IDQ to the pattern data DP according to the high-level test control signal TEST.

The data strobe signal generation circuit DG generates THE data strobe signal DQS. As shown in the timing chart of FIG. 4, the data strobe signal DQS is obtained by dividing the internal clock signal 2CLK by two in correspondence with the rising edges of the internal clock signal 2CLK (arrow A10 in FIG. 4). The data strobe signal DQS output from the data strobe signal generation circuit DG is input into the DLL circuit 10 via the output buffer OB1 and the input buffer IB1. In the DLL circuit 10, the delayed data strobe signal DDQS is generated by delaying the phase of the data strobe signal DQS by 90° (arrow A11 in FIG. 4). The delayed data strobe signal DDQS is input into the flip-flop FF3.

The flip-flop FF2 generates the delayed data signal DQR according to the internal clock signal 2CLK input from the clock selector CS. As shown in FIG. 4, the delayed data signal DQR is obtained by dividing the internal clock signal 2CLK by two in correspondence with the rising edges of the internal clock signal 2CLK (arrow A12 in FIG. 4). The delayed data signal DQR output from the flip-flop FF2 is fed back to the input buffer IB2 via the output buffer OB2 and is input to the flip-flop FF3.

As shown in FIG. 4, the toggle edges of the delayed data strobe signal DDQS are positioned at centers of portions of the delayed data signal DQR. Accordingly, the flip-flop FF3 captures the delayed data signal DQR in correspondence with the toggle edges of the delayed data strobe signal DDQS (arrow A13 in FIG. 4). At this time, the flip-flop FF3 can capture the data signal DQ with a sufficient time margin since the toggle edges of the delayed data strobe signal DDQS are positioned at the centers of portions of the delayed data signal DQR.

During the normal mode, the data signal DQ is output from the flip-flop FF2. When the loopback test is performed, the delayed data signal DQR is output from the flip-flop FF2. In the loopback test mode, therefore, the data strobe signal DQS and the delayed data signal DQR are fed back to the DDR-SDRAM interface circuit 1 with their edges phase-aligned with each other. Then the data strobe signal DQS is input to the DLL circuit 10, and the delayed data strobe signal DDQS phase-delayed by 90° is output from the DLL circuit 10. Accordingly, the edges of the delayed data strobe signal DDQS are positioned generally at the centers of portions of the delayed data signal DQR, so that the flip-flop FF3 can capture the delayed data signal DQR by using the delayed data strobe signal DDQS, thus enabling the loopback test.

The DLL circuit 10 can be provided in the loopback path. The DLL circuit 10 can change the phase angle according to the phase adjustment signal PAS. Therefore, it is possible to change the phase of the delayed data strobe signal DDQS arbitrarily by using the DLL circuit 10. Then the loopback test is performed by changing the amount of phase delay of the delayed data strobe signal DDQS in the range from 0 to 180° with respect to the delayed data signal DQR. The range of phase delay, in which the DDR-SDRAM interface circuit 1 can operate accurately, can be examined by changing the amount of phase delay in the test as described above. A margin test on the DDR-SDRAM interface circuit 1 with respect to changes in phase delay is thus made possible.

The DDR-SDRAM interface circuit includes the DLL circuit, the flip-flop and the first data signal output circuit. The DLL circuit is provided on the timing signal input path. The timing signal is input into the DLL circuit. The delayed timing signal delayed by a predetermined amount of delay is output from the DLL circuit. The predetermined amount of delay is determined in accordance with the DDR-SDRAM standard. For example, when the toggle edges of the delayed timing signal are set to coincide with centers of portions of the first data signal, the predetermined amount of delay is 90° or 270°, for example. In a case when the toggle edges of the delayed timing signal are set to be aligned with the toggle edges of the first data signal, the predetermined amount of delay is 0° or 180°, for example.

The flip-flop is provided on the first data signal input path. The first data signal and the delayed timing signal are input into the flip-flop. The flip-flop captures the first data signal according to the delayed timing signal. The first data signal output circuit is provided on the first data signal output path to output the first data signal. During the normal operation mode, the first data signal output circuit outputs the first data signal having a predetermined amount of phase difference with respect to the timing signal. In the loopback test mode, the first data signal output circuit outputs the first data signal in phase with the timing signal.

The DDR-SDRAM standard specifies that the toggle edges of the data strobe signal has a phase difference positions that the toggle edge of the data strobe signal positions at the centers of portions of the first data signal when writing data from the DDR-SDRAM interface circuit to the DDR-SDRAM. The DDR-SDRAM standard also specifies that the edges of the data strobe signal and the edges of the first data signal should coincide with each other in phase when reading out data from the DDR-SDRAM to the DDR-SDRAM interface circuit. When reading out data from the DDR-SDRAM to the DDR-SDRAM interface circuit, therefore, the data strobe signal and the first data signal phase-aligned are together input from the DDR-SDRAM into the DDR-SDRAM interface circuit.

In the DDR-SDRAM interface circuit 1 of the first embodiment, the loopback path can be formed by including the DLL circuit 10 and, therefore, various tests including an at-speed test can be performed more accurately. Also, for example, a roundtrip delay in the path from the data strobe signal generation circuit DG to the flip-flop FF3 can be tested more accurately. Consequently, reliability of a semiconductor device provided with the DDR-SDRAM interface circuit 1 can be improved and so on.

Since the loopback path can be formed by including the DLL circuit 10, the amount of phase delay in the loopback test can be changed arbitrarily by means of the DLL circuit 10. This enables to perform a margin test on the DDR-SDRAM interface circuit 1 with respect to various changes of phase delay.

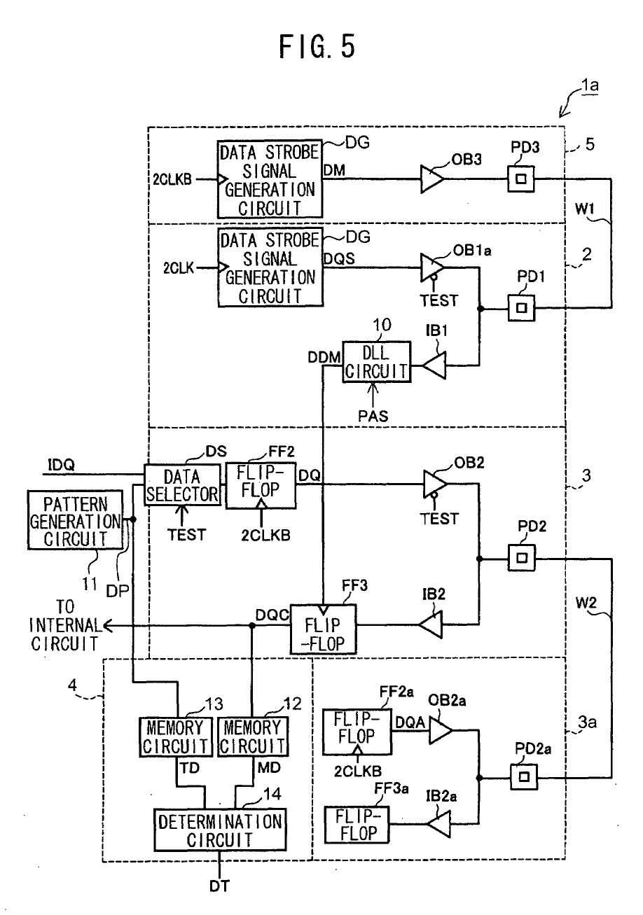

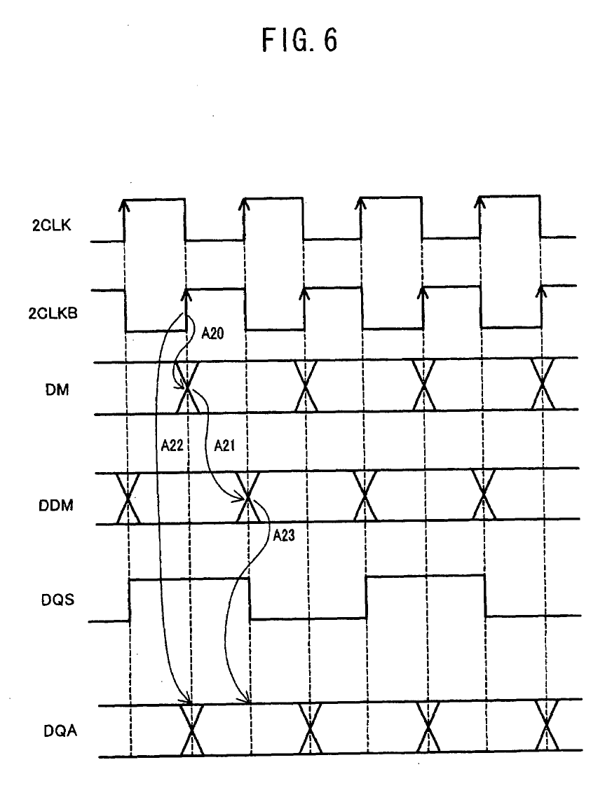

FIGS. 5 and 6 show a second embodiment. FIG. 5 is a diagram showing the circuit configuration of the second embodiment. A DDR-SDRAM interface circuit 1a includes a clock signal output section 5 and a second data signal input/output section 3a in addition to the DDR-SDRAM interface circuit shown in FIG. 3. The clock signal output section 5 includes a data mask signal generation circuit CG, an output buffer OB3 and an input/output pad PD3. The second data signal input/output section 3a includes a flip-flop FF2a for data signal output, an output buffer OB2a, an input/output pad PD2a, an input buffer IB2a, and a flip-flop FF3a for data signal capture. A test control signal TEST is input into an output buffer OB1a in the data strobe signal input/output section 2. The clock selector CS is not provided in the data signal input/output section 3. The internal opposite-phase clock signal 2CLKB is input into the flip-flop FF2. The input/output pads PD1 and PD3 are connected to each other by external wiring W1, while the input/output pads PD2 and PD2a are connected to each other by external wiring W2. In other respects, the circuit configuration is the same as that of the DDR-SDRAM interface circuit 1 shown in FIG. 3. Therefore no further detailed description is made of the configuration.

The operation of the DDR-SDRAM interface circuit 1a is described. When the test control signal TEST is set to the high level by the control circuit (not shown), the interface circuit enters the loopback test mode. According to the high-level test control signal TEST, the output buffer OB1a stops outputting the data strobe signal DQS. The output buffer OB2a enters a high-impedance state according to the high-level test control signal TEST. A path for feeding back the data in the output buffer OB2a to the input buffer IB2a is thereby formed. Also, a data mask signal DM is generated in the data mask signal generation circuit CG of the clock signal output section 5. As shown in the timing chart of FIG. 6, the data mask signal DM is obtained by dividing the internal opposite-phase clock signal 2CLKB by two in correspondence with the rising edges of the internal opposite-phase clock signal 2CLKB (arrow A20 in FIG. 6). Therefore, the data mask signal DM has a phase difference of 90° from the data strobe signal DQS. The data mask signal DM output from the data mask signal generation circuit CG is input into the DLL circuit 10 via the output buffer OB3, the input/output pad PD3, the external wiring W1, the input/output pad PD1 and the input buffer IB1. That is, as a signal used for generating a timing of capturing the data signal DQ, the data mask signal DM is input into the DLL circuit 10 instead of the data strobe signal DQS. In the DLL circuit 10, the delayed data mask signal DDM is generated by delaying the phase of the data mask signal DM by 90° (arrow A21 in FIG. 6). The delayed data mask signal DDM is input into the flip-flop FF3.

The flip-flop FF2a in the second data signal input/output section 3a generates the data signal DQA according to the internal opposite-phase clock signal 2CLKB (arrow A22 in FIG. 6). The data signal DQA output from the flip-flop FF2a is turned back to the data signal input/output section 3 via the output buffer OB2a, the input/output pad PD2a and the external wiring W2 and is input into the flip-flop FF3 via the input/output pad PD2 and the input buffer IB2. As shown in FIG. 6, the toggle edges of the delayed data mask signal DDM are positioned at centers of portions of the data signal DQA. Accordingly, the flip-flop FF3 captures the data signal DQA in correspondence with the toggle edges of the delayed data mask signal DDM (arrow A23 in FIG. 6).

During the loopback test mode in the second embodiment, the data mask signal DM is fed back instead of the data strobe signal DQS. According to the DDR-SDRAM standard, the edges of the data mask signal DM and the data signal DQA are phase-aligned with each other. Accordingly, the data signal DQA and the signal (data mask signal DM) used for generating a timing of capturing the data signal DQA are fed back to the DDR-SDRAM interface circuit 1a in a state of having their edges phase-aligned with each other. The delayed data mask signal DDM obtained by delaying the phase of the data mask signal DM by 90° is output from the DLL circuit 10 and the edges of the delayed data mask signal DDM are positioned at the centers of portions of the data signal DQA. Consequently, the flip-flop FF3 can capture the data signal DQA by using the delayed data mask signal DDM. This enables the loopback test.

In the DDR-SDRAM interface circuit 1a of the second embodiment, the data mask signal DM is fed back instead of the data strobe signal DQS in the loopback test. Thus, THE loopback path can be formed with the DLL circuit 10. Therefore various tests including an at-speed test can be performed more accurately.

Also, the interface circuit is configured so that the data signal DQA output from the second data signal input/output section 3a is fed back to the data signal input/output section 3 by using the external wiring W2. In this configuration, external wiring is included in both the data mask signal DM loopback path and the data signal DQA loopback path, so that the feedback paths can be evenly configured. Therefore, the various parameters of the feedback paths including the lengths, parasitic capacitances and resistance values can be equalized. The lengths of time of roundtrip delays of the data mask signal DM and the data signal DQA can be equalized, and this enables the loopback test to be performed more accurately.

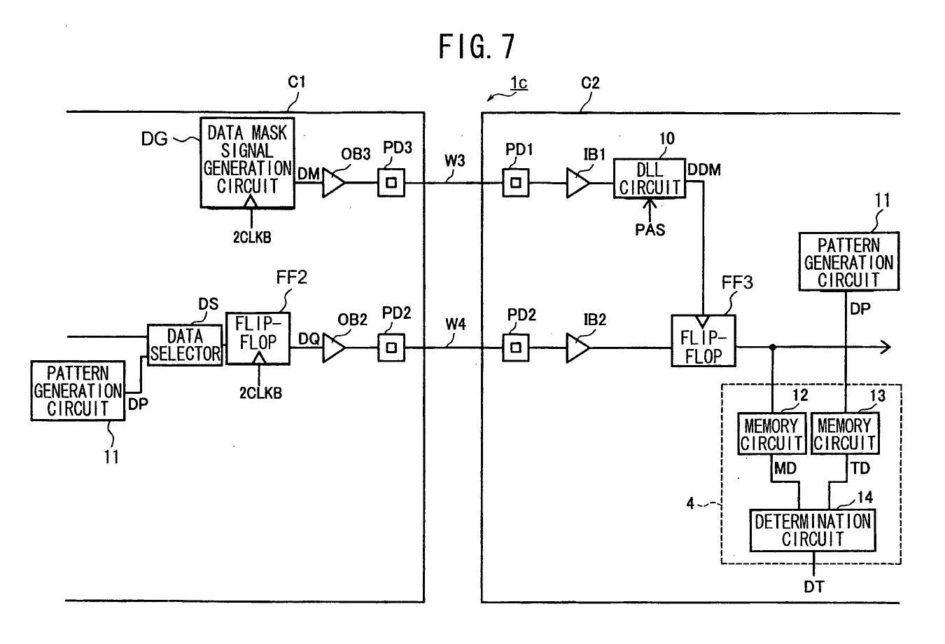

FIG. 7 shows a third embodiment. FIG. 7 is a diagram showing the circuit configuration of a testing system 1c according to the third embodiment. The testing system 1c for the DDR-SDRAM interface circuit includes semiconductor devices C1 and C2. The semiconductor devices C1 and C2 include the components of the DDR-SDRAM interface circuit 1a shown in FIG. 5 being distributed. The input/output pad PD3 of the semiconductor device C1 and the input/output pad PD1 of the semiconductor device C2 are connected to each other by external wiring W3. The input/output pad PD2 of the semiconductor device C1 and the input/output pad PD2 of the semiconductor device C2 are connected to each other by external wiring W4.

The flip-flop FF2 of the semiconductor device C1 outputs the data signal DQ to the semiconductor device C2. The data mask signal generation circuit CG outputs the data mask signal DM in phase with the data signal DQ to the semiconductor device C2. The data mask signal DM is input into the input/output pad PD1 of the semiconductor device C2. The data signal DQ is input into the input/output pad PD2. The delayed data mask signal DDM obtained by delaying the phase of the data mask signal DM by 90° is output from the DLL circuit 10 of the semiconductor device C2. The delayed data mask signal DDM and the data signal DQ are input into the flip-flop FF3 of the semiconductor device C2. In other respects, the circuit configuration is the same as that of the DDR-SDRAM interface circuit 1a shown in FIG. 5. Therefore no further detailed description is made of the configuration.

The operation of the DDR-SDRAM interface circuit testing system 1c in a case where the semiconductor device C1 is a reference sample while the semiconductor device C2 is a test object sample is described. As the reference sample, a sample of ideal characteristics (herein interchangeably also referred to as “golden sample”) is used in which the phase difference between the data mask signal DM and the data signal DQ is known to be extremely close to zero.

The data mask signal DM phase-aligned with the data signal DQ is output from the semiconductor device C1 to the semiconductor device C2. The edges of the delayed data mask signal DDM output from the DLL circuit 10 of the semiconductor device C2 are positioned at the centers of portions of the data signal DQ. Therefore, the flip-flop FF3 of the semiconductor device C2 can capture the data signal DQ by using the delayed data mask signal DDM. The data signal DQ captured by the flip-flop FF3 is successively stored in the memory circuit 12. The pattern data DP output from the pattern generation circuit 11 of the semiconductor device C2 is successively stored in the memory circuit 13. The determination circuit 14 determines whether or not the test result data MD output from the memory circuit 12 and the output pattern data TD output from the memory circuit 13 coincide with each other.

Since the semiconductor devices C1 and C2 are similar in structure to each other, the pattern data DP output from the pattern generation circuit 11 of the semiconductor device C1 and the pattern data DP output from the pattern generation circuit 11 of the semiconductor device C2 are similar to each other. Therefore, if the semiconductor device C2 has the setting/holding characteristics in conformity with the standard, the determination signal DT, indicating that the output pattern data TD and the test result data MD coincide with each other, is output from the determination circuit 14. If the semiconductor device C2 does not have the setting/holding characteristics in conformity with the standard, the determination signal DT, indicating that the output pattern data TD and the test result data MD do not coincide with each other, is output from the determination circuit 14. The communication test is thus completed.

In this system, communication paths are formed by using signal output paths of the semiconductor device C1 and signal input paths of the semiconductor device C2. Therefore, the output paths and the input paths are thus separated physically from each other. Also, a sample of ideal characteristics, in which the phase difference between the data mask signal DM and the data signal DQ is extremely close to zero, is used as a reference sample for the semiconductor device C1. In this way, phase variation between signals due to the semiconductor device C1 on the data transmitting side is eliminated. Consequently, a test of phase variation between signals with respect to the semiconductor device C2 on the data receiving side can be performed.

In the third embodiment, a communication test, in which signal output paths and signal input paths are physically separated from each other, is performed by using the semiconductor device C1 on the data transmitting side and the semiconductor device C2 on the data receiving side. Also, a reference sample for the semiconductor device C1 on the data transmitting side is used to eliminate phase variation between signals in the signal output paths. Thus, in the DDR-SDRAM interface circuit, the signal output paths and the signal input paths are formed separately from each other to enable various tests including an at-speed test with respect to the signal input paths only. The facility with which a cause of defect is identified can be improved because more precise tests can be performed.

Thus, for a test, because a sample with known characteristics may be provided, there is no need to provide a special tester for generation and reception of a test pattern. Various tests can be performed with a simpler arrangement. The shipping test cost can therefore be reduced.

The arrangement may alternatively be such that the semiconductor device C2 is a reference sample while the semiconductor device C1 is a test object sample. As the reference sample in this case, a sample of ideal characteristics, such as one in which the phase difference between the data signal DQ and the delayed data mask signal DDM input into the flip-flop FF3 is accurately 90°, is preferred. In this case, phase variation between signals in the signal input paths of the semiconductor device C2 on the data receiving side can be eliminated. Consequently, a test of phase variation between signals with respect to the signal output paths of the semiconductor device C1 on the data transmitting side only can be performed.

Each of the first and second semiconductor devices is not necessarily provided alone. A plurality of first or second semiconductor devices may be provided. The first semiconductor device includes the data signal output circuit and the timing signal output circuit. The timing signal output circuit generates and outputs a timing signal. The timing signal includes the data strobe signal or the data mask signal. The data signal output circuit generates the data signal in phase with the timing signal and outputs the data signal out of the first semiconductor device.

The second semiconductor device includes the DLL circuit and the flip-flop. The DLL circuit is provided on the data strobe signal input path. The timing signal is input from the first semiconductor device into the DLL circuit. The delayed timing signal, obtained by delaying the phase of the input timing signal by a predetermined amount of delay, is output from the DLL circuit. The predetermined amount of delay is an amount determined in accordance with the DDR-SDRAM standard. The flip-flop is provided on the data signal input path. The delayed timing signal and the data signal are input into the flip-flop. The flip-flop captures the data signal according to the delayed timing signal.

The DDR-SDRAM uses the timing signal when writing data from the DDR-SDRAM interface circuit to the DDR-SDRAM. The toggle edges of the timing signal are aligned with the edges of the data signal.

In the third embodiment, the timing signal is input from the first semiconductor device into the second semiconductor device at the time of the communication test. That is, the timing signal and the data signal having their edges phase-aligned with each other are input into the second semiconductor device. The timing signal is delayed by the predetermined amount in the DLL circuit to obtain the delayed timing signal. The toggle edges of the delayed timing signal are positioned at the centers of portions of the data signal. Consequently, the flip-flop can capture the data signal by using the delayed data mask signal, thus enabling the communication test.

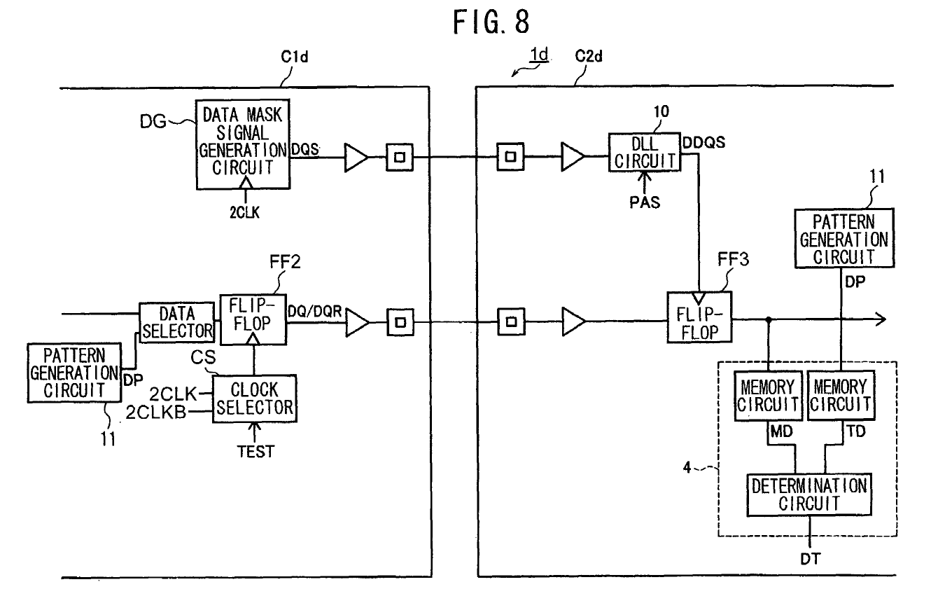

FIG. 8 shows a fourth embodiment. FIG. 8 is a diagram showing the circuit configuration of the fourth embodiment. A DDR-SDRAM interface circuit testing system 1d includes semiconductor devices C1d and C2d. The semiconductor device C1d includes the data strobe signal generation circuit DG and the clock selector CS, as contrasted with the semiconductor device C1 shown in FIG. 7. The data strobe signal generation circuit DG outputs the data strobe signal DQS based on the internal clock signal 2CLK input thereto. The internal clock signal 2CLK, the internal opposite-phase clock signal 2CLKB and the test control signal TEST are input into the clock selector CS. In other respects, the circuit configuration is the same as that of the DDR-SDRAM interface circuit testing system 1c shown in FIG. 7. Therefore no further detailed description is made of the configuration.

The operation of the DDR-SDRAM interface circuit testing system 1d in a case where the semiconductor device C1d is a reference sample while the semiconductor device C2d is a test object sample is described. When a communication test is performed by the testing system 1d, the test control signal TEST is set to a high level by the control circuit (not shown). In response to transition of the test control signal TEST to the high level, the clock selector CS changes the clock signal to be input into the flip-flop FF2 from the internal opposite-phase clock signal 2CLKB to the internal clock signal 2CLK. The flip-flop FF2 outputs the delayed data signal DQR based on the internal clock signal 2CLK. The data strobe signal DQS and the delayed data signal DQR are thereby input into the semiconductor device C2d, with their edges phase-aligned with each other. The edges of the delayed data strobe signal DDQS output from the DLL circuit 10 of the semiconductor device C2d are positioned at the centers of portions of the delayed data signal DQR. Consequently, the flip-flop FF3 of the semiconductor device C2d can capture the delayed data signal DQR by using the delayed data strobe signal DDQS.

In the testing system 1d of third embodiment, a communication test is performed with signal output paths and signal input paths being physically separated from each other by using the semiconductor device C1d on the data transmitting side and the semiconductor device C2d on the data receiving side. Thus, in the DDR-SDRAM interface circuit, the signal output paths and the single input paths are formed separately from each other to enable various tests including an at-speed test. Accordingly, more precise tests can be performed.

The embodiments are not limited the above-described. Various modifications and changes can be made without departing from the gist. In the third embodiment, the pattern generation circuit 11, the memory circuits 12 and 13, the determination circuit 14 and so on are provided in the DDR-SDRAM interface circuit and a built in self test (BIST) is performed. However, the embodiments are not limited to this form of implementation. At least one of these circuits may be provided on a test board for the DDR-SDRAM interface circuit. The chip overhead of the BIST circuit can be reduced in this way.

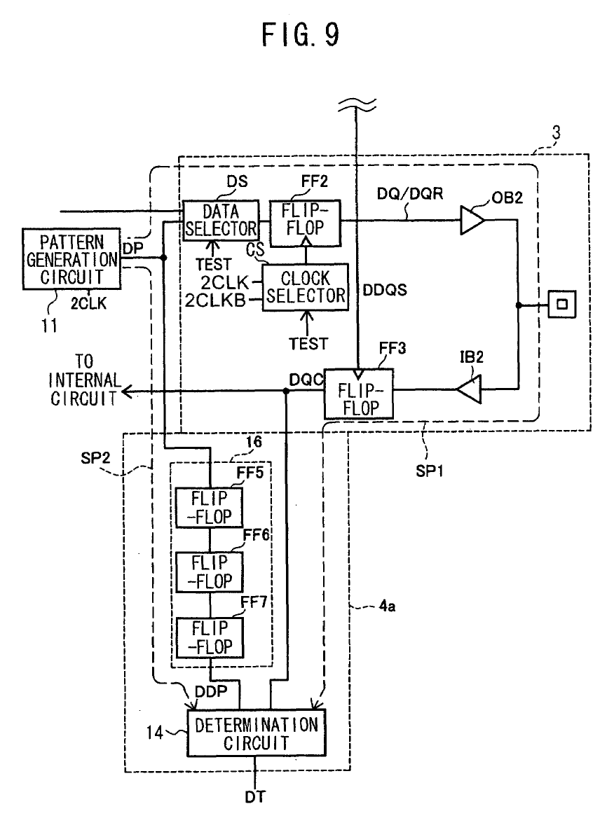

In the embodiments, each of the determination sections 4 shown in FIGS. 3, 5, 7, and 8 includes the memory circuits 12 and 13 and the determination circuit 14. However, the embodiment is not limited to this form. The determination section 4 may be configured as shown in FIG. 9. A determination section 4a includes a determination circuit 14 and a delay section 16. The delay section 16 includes flip-flops FF5 to FF7 connected in series. Pattern data DP is input into the flip-flop FF5. Delayed pattern data DDP is output from the flip-flop FF7. The delayed pattern data DDP and the obtained data signal DQC are input into the determination circuit 14. In other respects, the circuit configuration is the same as that of the DDR-SDRAM interface circuit 1 shown in FIG. 3. Therefore no further detailed description is made of the configuration.

The operation of the determination section 4a is as described below. The pattern generation circuit 11 sequentially outputs pattern data DP according to the internal clock signal 2CLK. The pattern data DP output from the pattern generation circuit 11 diverge into two. One diverging data from the pattern generation circuit 11 is input into the flip-flop FF3 via the data selector DS, the flip-flop FF2, the output buffer OB2 and the input buffer IB2. The flip-flop FF3 captures the data signal DQ according to the delayed data strobe signal DDQS and sequentially outputs the obtained data signal DQC. The obtained data signal DQC output from the flip-flop FF3 is input into the determination circuit 14 (signal path SP1 in FIG. 9). At this time, the obtained data signal DQC is a signal that is added a delay DDT1 to pattern data DP by the signal path SP1.

The other diverging data from the pattern generation circuit 11 is input into the determination circuit 14 as delayed pattern data DDP via the flip-flops FF5 to FF7 in the delay section 16 (signal path SP2 in FIG. 9). At this time, the delayed pattern data DDP is given a delay DDT2 by the delay section 16. The number of flip-flop stages in the delay section 16 is set in advance so that the delay DDT2 given by the delay section 16 and the delay DDT1 given by the signal path SP1 are equal to each other.

In this way, the delayed pattern data DDP can be set in correspondence with the delay of the obtained data signal DQC. Accordingly, the pattern data DP output and diverging from the pattern generation circuit 11 and the obtained data signal DQC reach the determination circuit 14 simultaneously. The determination circuit 14 can determine a coincidence/non-coincidence between the two data according to the data input and can therefore perform the determination operation in real time. This enables the communication test to be performed at a higher speed.

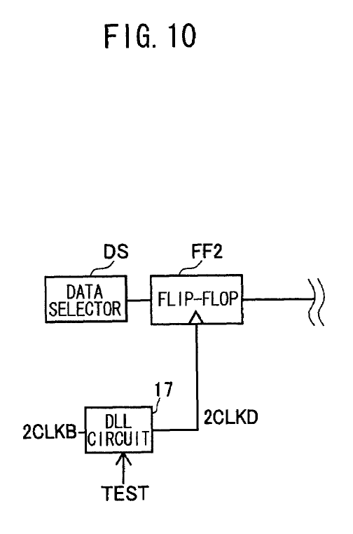

In the embodiments, each of the flip-flops FF2 shown in FIGS. 3, 8, and 9 includes the clock selector CS. However, the embodiment is not limited to this form. As shown in FIG. 10, the flip-flop FF2 may includes a DLL circuit 17 instead of the clock selector CS. The internal clock signal 2CLK and the test control signal TEST are input into the DLL circuit 17. The delayed internal clock signal 2CLKD output from the DLL circuit 17 is input into the flip-flop FF2. In other respects, the circuit configuration is the same as that of the DDR-SDRAM interface circuit 1 shown in FIG. 3. Therefore, no further detailed description is made of the configuration.

During the normal mode, the test control signal TEST is set to a low level by the control circuit (not shown). According to the low-level test control signal, the DLL circuit 17 outputs the delayed internal clock signal 2CLKD without shifting the phase of the internal opposite-phase clock signal 2CLKB. The flip-flop FF2 generates and outputs the data signal DQ according to the delayed internal clock signal 2CLKD. In the loopback test mode, the test control signal TEST is set to a high level. According to the high-level test control signal, the DLL circuit 17 shifts by 90° the phase of the internal opposite-phase clock signal 2CLKB to be input into the flip-flop FF2, generates the delayed internal clock signal 2CLKD corresponding to the internal clock signal 2CLK, and outputs the delayed internal clock signal 2CLKD. The flip-flop FF2 generates and outputs the delayed data signal DQR according to the delayed internal clock signal 2CLKD.

The loopback test can be performed as described above. If the DLL circuit 17 is used with another DLL circuit (DLL circuit 10 for example), the need for the clock selector CS can be eliminated to reduce the circuit scale. If the loopback test is performed by changing the amount of delay in the DLL circuit 17 in the range from 0 to 180°, a margin test on the DDR-SDRAM interface circuit with respect to changes in phase delay can be performed.

For purposes of explanation, in the above description, numerous specific details are set forth in order to provide a thorough understanding of the invention. It will be apparent, however, to one skilled in the art that the invention can be practiced without these specific details. In other instances, well-known structures and devices are shown in block diagram form in order to avoid obscuring the invention.

While the invention has been described in conjunction with the specific embodiments thereof, it is evident that many alternatives, modifications, and variations will be apparent to those skilled in the art. Accordingly, embodiments of the invention as set forth herein are intended to be illustrative, not limiting. There are changes that may be made without departing from the spirit and scope of the invention.

What is claimed is:

1. A memory interface circuit including a first data output circuit which outputs a data signal based on a data strobe signal, the memory interface circuit comprising:
a first delay-locked loop circuit that adjusts a delay of the data strobe signal and outputs the data strobe signal at a first timing; and
a second data output circuit that outputs the data signal at a second timing different from the first timing during a normal operation, and outputs the data signal at the first timing during a test operation.

2. The memory interface circuit according to claim 1, further comprising:
a clock selection circuit that supplies a first clock signal to the second data output circuit during the normal operation and supplies a second clock signal to the second data output circuit during the test operation.

3. The memory interface circuit according to claim 1, wherein the first clock signal and the second clock signal are phase-inverses of each other.

4. The memory interface circuit according to claim 1, further comprising:
a second delay-locked loop circuit that receives an internal clock signal, shifts the internal clock signal, and outputs the internal clock signal to the first output circuit.

5. The memory interface circuit according to claim 1, wherein the data strobe signal and the data signal are signals output from a memory.

6. The memory interface circuit according to claim 1, further comprising:
a data selection circuit that changes the data signal between a normal mode and a test mode.

7. The memory interface circuit according to claim 1, further comprising:
a determination circuit that compares the data signal output from the first data output circuit and a pattern signal, and outputs a result of the comparison.

8. The memory interface circuit according to claim 7, further comprising:
a first memory circuit that stores the data signal; and
a second memory circuit that stores the pattern signal.

9. The memory interface circuit according to claim 7, further comprising:
a delay circuit that delays the data signal and outputs the delayed data signal to the determination circuit.

10. The memory interface circuit according to claim 1, wherein a phase difference between the first timing and the second timing is 90 degrees.

11. The memory interface circuit according to claim 1, wherein the test operation is a loopback test mode.

12. A memory interface circuit including a first data output circuit which outputs a data signal based on a data strobe signal, the memory interface circuit comprising:
a first circuit that outputs a first signal at a first timing during a test operation;
a delay-locked loop circuit that adjusts a delay of the first signal and outputs to the first data output circuit the first signal at a second timing different from the first timing; and
a second data output circuit that outputs the data signal to the first data output circuit during the test operation.

13. The memory interface circuit according to claim 12, wherein the first signal is supplied to the delay-locked loop circuit via a first wiring and the data signal is supplied to the first data output circuit via a second wiring.

14. The memory interface circuit according to claim 12, wherein the first circuit is a data mask signal generation circuit which produces a data mask signal.

15. The memory interface circuit according to claim 12, wherein the memory interface circuit is mounted in a first semiconductor device and the first circuit and the second circuit are mounted in a second semiconductor device.

16. The memory interface circuit according to claim 12, further comprising:
a determination circuit that compares the data signal output from the first data output circuit and a pattern signal and outputs a result of the comparison.

17. A memory system comprising:
a memory; and
a memory interface circuit provided between the memory and a semiconductor device, the memory interface circuit including:
a first data output circuit that outputs a data signal based on a data strobe signal;
a first DLL circuit that adjusts a delay of the data strobe signal and outputs the data strobe signal at a first timing; and
a second data output circuit that outputs the data signal at a second timing different from the first timing during a normal operation and outputs the data signal at the first timing during a test operation.

18. The memory system according to claim 17, wherein the data strobe signal and the data signal are signals output from the memory.

19. A memory system comprising:
a memory; and
a memory interface circuit provided between the memory and a semiconductor device, the memory interface circuit including:
a first data output circuit that outputs a data signal based on a data strobe signal;
a first circuit that outputs a first signal at a first timing during test operation;
a delay-locked loop circuit that adjusts a delay of the first signal and outputs to the first data output circuit the first signal at a second timing different from the first timing; and
a second circuit that outputs the data signal at the first timing to the first data output circuit during the test operation.

20. The memory system according to claim 19, wherein the data strobe signal and the data signal are signals output from the memory.
